(19) United States
(12) Patent Application Publication
(10) Pub. No.: US 2023/0314659 A1
(43) Pub. Date: Oct. 5, 2023

(54) METASTRUCTURES INCLUDING NANOPARTICLES

(71) Applicant: NILT Switzerland GmbH, Horen (CH)

(72) Inventor: James Eilertsen, Zug (CH)

(21) Appl. No.: 18/026,725

(22) PCT Filed: Sep. 16, 2021
(86) PCT No.: PCT/EP2021/075515

§ 371 Date: Mar. 16, 2023

Related U.S. Application Data
(60) Provisional application No. 63/081,139, filed on Sep. 21, 2020.

(51) Int. Cl. G02B 1/00; G03F 7/00

(52) U.S. Cl. CPC G02B 1/002; G03F 7/0002; G03F 7/0005

(57) ABSTRACT

A method includes pressing a face of a stamp into a replication material disposed on a substrate, to cause the replication material to have a predetermined characteristic, in which a plurality of nanoparticles are embedded in the replication material, the plurality of nanoparticles having a size distribution with a first local maximum at a first diameter and a second local maximum at a second, different diameter, and in which the plurality of nanoparticles includes a first subset of nanoparticles having diameters closer to the first diameter than to the second diameter and a second subset of nanoparticles having diameters closer to the second diameter than to the first diameter; curing the replication material; and removing the face of the stamp from contact with the replication material.

### FIELD OF THE DISCLOSURE

The present disclosure relates to optical metastructures including nanoparticles.

### BACKGROUND

In a replication process, a given structure or a negative thereof is reproduced. In some cases, a structure is reproduced in a replication material disposed on a substrate.

### SUMMARY

In one aspect, the present disclosure describes a method that includes pressing a face of a stamp into a replication material disposed on a substrate, to cause the replication material to have a predetermined characteristic, in which a plurality of nanoparticles are embedded in the replication material, the plurality of nanoparticles having a size distribution with a first local maximum at a first diameter and a second local maximum at a second, different diameter, and in which the plurality of nanoparticles includes a first subset of nanoparticles having diameters closer to the first diameter than to the second diameter and a second subset of nanoparticles having diameters closer to the second diameter than to the first diameter; curing the replication material; and removing the face of the stamp from contact with the replication material.

Implementations of this method may have one or more of the following characteristics. Nanoparticles in the first subset have a first refractive index, and nanoparticles in the second subset have a second refractive index different from the first refractive index. At least some of the plurality of nanoparticles have a negative thermal expansion coefficient. The nanoparticles having the negative thermal expansion coefficient are exclusively in the first subset or the second subset of the plurality of nanoparticles. The first diameter and the second diameter are different by at least about 20 nm. The method includes, subsequent to removing the face of the stamp, sintering the nanoparticles to one another, in which the sintered nanoparticles form one or more optical metastructures. Sintering the nanoparticles includes removing at least a portion of the replication material. The predetermined characteristic includes a surface structure of the replication material. The surface structure provides an optical functionality. The predetermined characteristic includes an optical metastructure functionality.

In another aspect, the disclosure describes a method that includes pressing a face of a stamp into a replication material disposed on a substrate, to cause the replication material to have a predetermined characteristic, in which a plurality of nanoparticles are embedded in the replication material, at least a portion of the plurality of nanoparticles having a negative thermal expansion coefficient; applying heat to the replication material; and removing the face of the stamp from contact with the replication material.

Implementations of this method may have one or more of the following characteristics. At least some of the plurality of nanoparticles having a negative thermal expansion coefficient include an AM₂O₈ material. The face of the stamp is removed from contact with the replication material while the replication material is at a temperature above about 100° C. The plurality of nanoparticles has a size distribution with a first local maximum at a first diameter and a second local maximum at a second diameter, and the plurality of nanoparticles includes a first subset of nanoparticles having diameters closer to the first diameter than to the second diameter and a second subset of nanoparticles having diameters closer to the second diameter than to the first diameter. The nanoparticles having the negative thermal expansion coefficient are exclusively in the first subset or the second subset of the plurality of nanoparticles. The method includes, subsequent to removing the face of the stamp, sintering the plurality of nanoparticles to one another, in which the sintered nanoparticles form one or more optical metastructures. The predetermined characteristic includes a surface structure of the replication material. The surface structure provides an optical functionality. The predetermined characteristic includes an optical metastructure functionality.

In another aspect, the disclosure describes a method that includes pressing a face of a stamp into a replication material disposed on a substrate, to cause the replication material to have a predetermined characteristic, in which a plurality of nanoparticles are embedded in the replication material; curing the replication material; and sintering the plurality of nanoparticles to form an optical metastructure formed by the plurality of nanoparticles.

Implementations of this method may include one or more of the following characteristics. Sintering the plurality of nanoparticles causes the removal of at least some of the replication material. The method includes burning off at least some of the replication material. At least some of the nanoparticles have a negative thermal expansion coefficient. The plurality of nanoparticles has a size distribution with a first local maximum at a first diameter and a second local maximum at a second, different diameter.

The disclosure also describes optical devices. For example, the disclosure describes an optical device including a substrate; and an optical metastructure on a surface of the substrate, the optical metastructure including a replication material, and a plurality of nanoparticles embedded in the replication material, the plurality of nanoparticles having a size distribution with a first local maximum at a first diameter and a second local maximum at a second, different diameter. In some implementations, the plurality of nanoparticles includes a first subset of nanoparticles having diameters closer to the first diameter than to the second diameter and a second subset of nanoparticles having diameters closer to the second diameter than to the first diameter, and the nanoparticles of the first subset are composed of a different material from the nanoparticles of the second subset. In some implementations, at least some of the plurality of nanoparticles have a negative thermal expansion coefficient.

The disclosure also describes an optical device including a substrate and an optical metastructure on a surface of the substrate, the optical metastructure including a replication material, and a plurality of nanoparticles embedded in the replication material, at least some of the plurality of nanoparticles having a negative thermal expansion coefficient. In some implementations, at least some of the plurality of nanoparticles having a negative thermal expansion coefficient include an AM₂O₈ material. In some implementations, the plurality of nanoparticles has a size distribution with a first local maximum at a first diameter and a second local maximum at a second, different diameter.

The disclosure also describes an optical device including a substrate and an optical metastructure on a surface of the substrate, the optical metastructure composed of a plurality of nanoparticles fused to one another, the plurality of nanoparticles having a size distribution with a first local maximum at a first diameter and a second local maximum at a second, different diameter. In some implementations, the plurality of nanoparticles includes a first subset of nanoparticles having diameters closer to the first diameter than to the second diameter and a second subset of nanoparticles having diameters closer to the second diameter than to the first diameter, and the nanoparticles of the first subset are composed of a different material from the nanoparticles of the second subset. In some implementations, at least some of the plurality of nanoparticles have a negative thermal expansion coefficient.

The disclosure also describes an optical device including a substrate and an optical metastructure on a surface of the substrate, the optical metastructure composed of a plurality of nanoparticles fused to one another, at least some of the plurality of nanoparticles having a negative thermal expansion coefficient. In some implementations, at least some of the plurality of nanoparticles having a negative thermal expansion coefficient include an AM₂O₈ material. In some implementations, the plurality of nanoparticles has a size distribution with a first local maximum at a first diameter and a second local maximum at a second, different diameter.

The disclosure also describes modules. For example, the disclosure describes a module including at least one of a light-emitting device or a light-sensitive device; and an optical device in accordance with the optical devices described in the disclosure, in which the optical device is configured (i) to interact with light generated by the light emitting device or (ii) to interact with light incident on the module such that light passing through the optical device is received by the light-sensitive device.

Embodiments of the subject matter described in this specification can be implemented to realize one or more of the following advantages. In some implementations, for example, structures may have a higher and/or more uniform index of refraction, in some cases resulting in improved optical performance. In some implementations, a packing density of embedded or sintered nanoparticles may be increased. In some implementations, mechanical damage during a replication process may be reduced. In some implementations, mechanical robustness in completed devices may be increased.

The details of one or more implementations are set forth in the accompanying drawings and the description below. Other aspects, features and advantages will be apparent from the description and drawings, and from the claims.

### BRIEF DESCRIPTION OF THE DRAWINGS

FIGS. 1A-1D are schematics showing an example of a fabrication process including a replication material and nanoparticles.

FIG. 2 is a plot showing an example of a multimodal nanoparticle size distribution.

FIGS. 3A-3E are schematics showing an example of a fabrication process including a replication material and nanoparticles.

FIG. 4 is a schematic showing an example optical module.

### DETAILED DESCRIPTION

The present disclosure describes replication processes and devices. In certain implementations, this disclosure describes imprinting a replication material in which are embedded nanoparticles having a bimodal size distribution and/or a negative thermal expansion coefficient.

Advanced optical elements may include a metasurface, which refers to a surface with distributed small structures (e.g., meta-atoms) arranged to interact with light in a particular manner. For example, a metasurface, which also may be referred to as a metastructure, can be a surface with a distributed array of nanostructures. The nanostructures may, individually or collectively, interact with light waves. For example, the nanostructures or other meta-atoms may change a local amplitude, a local phase, or both, of an incoming light wave.

When meta-atoms (e.g., nanostructures) of a metasurface are in a particular arrangement, the metasurface may act as an optical element such as a lens, lens array, beam splitter, diffuser, polarizer, bandpass filter, or other optical element. In some instances, metasurfaces may perform optical functions that are traditionally performed by refractive and/or diffractive optical elements. The meta-atoms may be arranged, in some cases, in a pattern so that the metastructure functions, for example, as a lens, grating, coupler or other optical element. In other instances, the meta-atoms need not be arranged in a pattern, and the metastructure can function, for example, as a fanout grating, diffuser or other optical element. In some implementations, the metasurfaces may perform other functions, including polarization control, negative refractive index transmission, beam deflection, vortex generation, polarization conversion, optical filtering, and plasmonic optical functions.

A metastructure can be transferred, for example, to a curable resin by replication techniques.

In general, replication refers to a technique by means of which a given structure is reproduced, e.g., etching, embossing or molding. In an example of a replication process, a structured surface is embossed into a liquid or plastically deformable material (a “replication material”), then the material is hardened, e.g., by curing using ultraviolet (UV) radiation or heating, and then the structured surface is removed. Thus, a negative of the structured surface (a replica) is obtained.

The replicated structure provides a mechanical, electrical, or optical functionality (or a combination of those functionalities) due to the structure imposed by the structured surface.

In some cases, replication may be implemented by stamping processes. In the case of a stamping process, which also may be referred to as an imprinting process, the structured surface is a surface of a stamp that is pressed into the liquid or plastically deformable material (or has the liquid or plastically deformable material pressed into it).

“Imprinting,” as used in this disclosure, may include other processes such as one or more of embossing, debossing, stamping, or nano-imprinting.

While in some implementations the liquid or plastically deformable material in an imprinting process is a bulk material (for example, a block of material), in other implementations the liquid or plastically deformable material is a layer or droplet (e.g., a coating) provided on a substrate surface.

Although replication provides the possibility of low-cost and high-throughput fabrication, in some cases the use of the liquid or plastically deformable material (the “replication material”) comes with possible drawbacks. For example, in some cases, the replication material may have a lower refractive index than would otherwise be desirable for optical applications. In some cases, structures formed by the replication material may be damaged mechanically during or subsequent to the replication process.

Therefore, in some cases, it is beneficial to embed nanoparticles having particular characteristics in the replication material, as described in this disclosure.

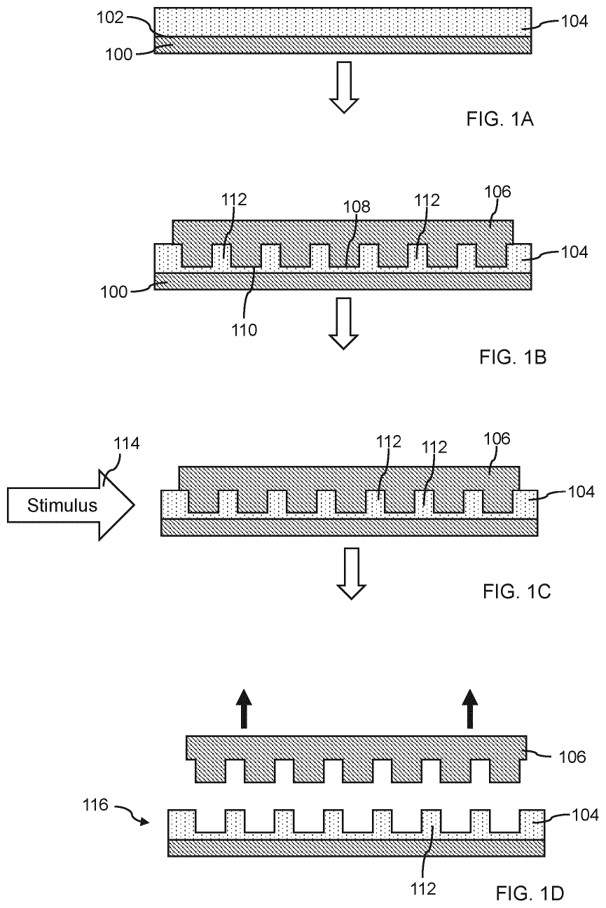

As shown in FIG. 1A, some implementations include a substrate 100 having a substrate surface 102 on which is disposed a replication material 104. In various implementations, the substrate 100 is composed of one or more of a semiconductor material, a polymer material, or a composite material including metals and polymers, or polymers and glass materials. In some implementations, the substrate 100 includes hardenable materials such as thermally and/or UV-curable polymers. In some implementations, the substrate 100 is transparent, e.g., a glass. In some implementations, the substrate 100 is fully or partially flexible, for example, a plastic such as poly-4,4′-oxydiphenylene pyromellitimide (Kapton).

In some implementations, the substrate 100 includes structures not shown in FIG. 1A, e.g., metasurfaces, waveguides, or other optical structures. In some implementations, the substrate surface 102 is not flat, e.g., curved or stepped.

Replication material 104 is disposed on the substrate surface 102 and is imprinted using a stamp 106. In some implementations, the replication material 104 is deposited onto the substrate surface 102, after which the stamp 106 is brought into contact with the replication material 104. Examples of methods for depositing the replication material 104 include printing (e.g., inkjet printing), jetting, dispensing, screenprinting, dip coating, and spin coating. In some implementations, the replication material 104 is deposited in portions of precisely known volumes (e.g., in volumes exact to within less than 3% of the deposited volume of each portion).

In some implementations, the replication material 104 is provided on the stamp 106 (e.g., onto the structured stamp surface 108), and the stamp 106 is then brought towards the substrate 100 (or has the substrate 100 brought towards it), such that the replication material 104 is disposed on the substrate 100 as a result of relative movement of the stamp 106 and the substrate 100.

The stamp 106 may be composed of a variety of materials, including a cured replication material and/or a patterned semiconductor wafer (e.g., a patterned silicon wafer), in some implementations including deposited metal layers. In some implementations, all or part of the stamp 106 is transparent, e.g., is composed of glass. In some implementations, the stamp 106 is thin and/or flexible, e.g., composed of polycarbonate foil. In some implementations, structured features of the stamp 106, such as the structured stamp surface 108, are composed of a polymer, e.g., PDMS.

The replication material 104 includes, in various implementations, one or more of a polymer, a spin-on-glass, or any other material that may be structured in a replication process. Suitable materials for replication include, for example, hardenable (e.g., curable) polymer materials or other materials which are transformable in a hardening or solidification step (e.g., a curing step) from a liquid or plastically deformable state into a solid state. For example, in some implementations the replication material 104 is a UV-curable and/or thermally-curable epoxy or resin (e.g., a photoresist). In some implementations, the replication material 104 is transparent before and/or after curing.

The replication material 104, in some implementations, has characteristics suitable for a device resulting from the replication. For example, the replication material (in either as-deposited or cured form) may have a particular refractive index, thermal or electrical conductivity, or chemical or physical resistance (e.g., low reactivity with atmospheric oxygen). A wide variety of materials suitable for replication may be used.

Imprinting by the stamp 106 causes the replication material 104 to have a predetermined characteristic.

For example, in some implementations, the replication material 104 is imprinted such that the replication material 104, after imprinting, has a particular thickness or range of thicknesses. In accordance with some implementations, the replication material 104 is imprinted to have a thickness anywhere from the nanometer range to the millimeter range, or larger.

In some implementations, the replication material 104 is imprinted such that a surface of the replication material 104 has a flatness within a desired range and/or a roughness within a desired range. For example, in some implementations, a face of the stamp is smooth, such that a surface of the replication material after imprinting is smooth.

In some implementations, the predetermined characteristic of the replication material 104 is an optical functionality based at least in part on a structure of a surface of the stamp 106. For example, as shown in FIG. 1B, the structured stamp surface 108 of the stamp 106 leaves a corresponding structured surface 110 in the replication material 104. For example, after imprinting (in some implementations, including after curing), in some implementations the replication material forms diffractive optical elements including many pixels or individual structures (e.g., structures 112 in FIG. 1D). The structures 112 include, in some implementations, one or more of pillars, posts, or ridges, in some implementations arranged in arrays or other patterns. In some implementations, each structure 112 has a dimension less than about 100 μm, less than about 20 μm, or less than about 1 μm.

In some implementations, the optical functionality includes one or more of lensing, focusing, reflecting or anti-reflecting, beamsplitting, or optical diffusing. In some implementations, the structures 112 are microlenses, such that a portion of replication material 104 after imprinting forms a microlens array. In some implementations, the replication material 104 after imprinting forms an optical metastructure or a group of optical metastructures, the optical metastructure or group of optical metastructures providing the optical functionality.

In some implementations, the predetermined characteristic is a non-optical functionality, e.g., hydrophobicity or hydrophilicity, which in some cases is determined by the form of the structures 112.

A plurality of nanoparticles (not shown) are embedded in the replication material 104. These nanoparticles may provide improved optical performance and/or mechanical robustness to devices.

In some implementations, the nanoparticles represent a majority of a weight of the mixture that includes the nanoparticles and the replication material. For example, in some implementations, the mixture is about 80% nanoparticles by weight and about 20% replication material by weight. In some implementations, the mixture is between about 60% nanoparticles by weight and about 90% nanoparticles by weight. In some implementations, nanoparticles represent less than about 50% of the weight of the mixture.

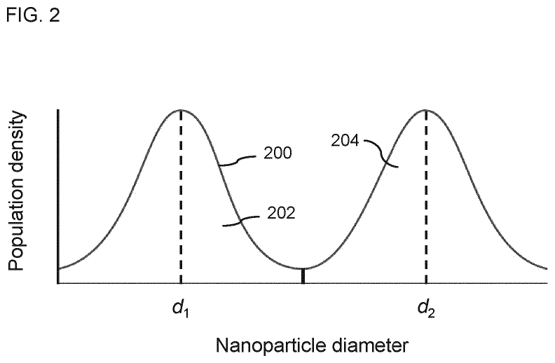

In some implementations, the nanoparticles have sizes distributed according to a multimodal distribution. For example, as shown in FIG. 2, in some implementations the nanoparticles have diameters following a bimodal distribution 200. The bimodal distribution 200 has a first local population maximum at diameter d₁ and a second local population maximum at diameter d₂, d₂ being different from d₁. Nanoparticle diameters may be described as having a bimodal distribution of nanoparticle diameters when, for example, the nanoparticles are divided into two subsets of nanoparticles, each subset having a different respective average diameter and the diameters within each subset being distributed about that average diameter. In the example of FIG. 2, a first subset 202 includes nanoparticles having diameters closer to d₁ than to d₂, and a second subset 204 (divided from the first subset 202 by the line segment 206) includes nanoparticles having diameters closer to d₂ than to d₁.

“Diameter,” as used in this disclosure, is used broadly to include at least widths and cross-body dimensions of nanoparticles, even when the nanoparticles are not spherical. For example, in some implementations the nanoparticles are obloid and/or irregularly shaped. In some implementations, at least some of the nanoparticles are substantially spherical and have a size defined by a substantially uniform diameter.

“Nanoparticle,” as used in this disclosure, is used broadly to refer to microscopic elements embedded in the replication material. In various implementations, nanoparticles have diameters greater than about 1 nm and less than about 1 micron. In some implementations, the nanoparticles have diameters between about 10 nm and about 100 nm.

In some implementations, the first subset 202 and the second subset 204 are differently-sized nanoparticles formed from the same material. In some implementations, the first subset 202 and the second subset 204 are formed from different materials.

In some implementations, some or all of the nanoparticles include a metal oxide, e.g., TiO₂. In some implementations, some or all of the nanoparticles include a transition metal oxide (e.g., VO₂, NiO, CoO, MnO, or FeO), an intermetallic compound, a pure element (e.g., Fe), a chalcogenide (e.g., TiS₂), and/or an antimonide (e.g., CoSb₃). In some implementations, some or all of the nanoparticles include a metal.

In some implementations, some or all of the nanoparticles have a higher refractive index than the refractive index of the replication material. For example, in some implementations, the plurality of nanoparticles have refractive indices, for visible light, of higher than about 1.7, higher than about 1.8, higher than about 1.9, or higher than about 2.0. In some implementations, nanoparticles of the first subset 202 have a first refractive index and nanoparticles of the second subset 204 have a second refractive index different from the first refractive index.

In some implementations, nanoparticles of the first subset have diameter d₁ and nanoparticles of the second subset have diameter d₂, e.g., there is essentially no spread in the diameters about these local diameter maxima. However, in some implementations, as in the example of FIG. 2, the respective subsets 202, 204 include nanoparticles of varying diameters, the respective distributions being characterized by respective standard deviations. In some implementations, the difference between d₁ and d₂ is greater than the sums of the respective standard deviations of the two subsets 202, 204.

In some implementations, d₁ is about 10 nm and d₂ is about 30 nm. In some implementations, the difference between d₁ and d₂ is greater than about 10 nm, greater than about 20 nm, or greater than about 40 nm. In some implementations, the difference between d₁ and d₂ is about equal to twice d₁. In some implementations, d₂ is greater than about twice d₁.

In some implementations, nanoparticles having diameter d₁ and nanoparticles having diameter d₂ are present in different concentrations. For example, in some implementations, nanoparticles of the larger diameter d₂ are present in greater proportion than nanoparticles of the smaller diameter d₁, which may promote improved packing. For example, embedded nanoparticles may have a composition of about 90% d₂ and about 10% d₁, or about 80% d₂ and about 20% d₁. However, in some implementations, a nanoparticle composition may be about 50% d₂ and about 50% d₁.

The multimodal distribution of nanoparticle diameters (e.g., in the example of FIG. 2, the bimodal distribution) causes a greater packing density of nanoparticles than if the nanoparticles were of one uniform size. For example, optimal packing of mono-sized spheres can provide a densest packing of about 74% of volume, whereas optimal packing densities of greater than about 80% or, in some implementations, greater than about 90% can be provided for a two-sized sphere distribution. In some implementations according to this disclosure, the nanoparticles are not perfectly spherical, and the nanoparticle diameters are distributed according to a multimodal distribution rather than having several discrete diameters, but the general principle that the multimodal distribution causes a higher packing density still holds.

Although FIG. 2 shows a bimodal distribution, in some implementations, the nanoparticles have diameters following a trimodal distribution or a higher order distribution.

Referring back to the process of FIGS. 1A-1D, as shown in FIG. 1C, a stimulus 114 is applied to the replication material 104, partially or wholly curing the replication material 104. In some implementations, the stimulus 114 includes heat, e.g., the substrate 100 and stamped replication material 104 are placed in a furnace. In some implementations, the stimulus 114 includes ultraviolet light illumination. In some implementations, the stimulus 114 includes both heat and ultraviolet light illumination.

In the example of FIG. 1C, the stimulus 114 is applied while the stamp 106 is maintained in contact with the replication material 104. However, in some implementations the stimulus 114 is applied while the stamp 106 is not in contact with the replication material 104, e.g., the stamp 106 is removed and then the stimulus 114 is applied.

As shown in FIG. 1D, subsequent to curing, the stamp 106 is removed, leaving an optical device 116. In the optical device 116, the replication material 104 has the predetermined characteristic imposed by the stamp 106. As described throughout this disclosure, the predetermined characteristic may include an optical functionality. For example, in some implementations the imprinted replication material 104 in the optical device 116 forms one or more optical metastructures.

Because of the presence of the nanoparticles in the replication material 104 of the optical device 116, the mixture of the nanoparticles and the replication material 104 has a higher refractive index than if there were no nanoparticles in the replication material 304. In some implementations, this higher refractive index improves an optical functionality of the optical device 116, e.g., increases a strength of interactions between the optical device 116 and light incident on or generated by the optical device 116. Because the nanoparticles have a multimodal size distribution, the nanoparticles are packed more efficiently into the replication material 104, and the mixture has a correspondingly higher and/or more uniformly high refractive index. A higher and/or more uniform refractive index may cause improved optical functioning in resulting optical devices.

In some implementations, some or all of the nanoparticles embedded in a replication material have a negative thermal expansion coefficient (NTE). NTE materials, in contrast to many known materials, contract when heated rather than expand. Water is a commonly encountered NTE material. However, solid NTE nanoparticles also can be formed, and these NTE nanoparticles can be embedded into replication materials as described in this disclosure.

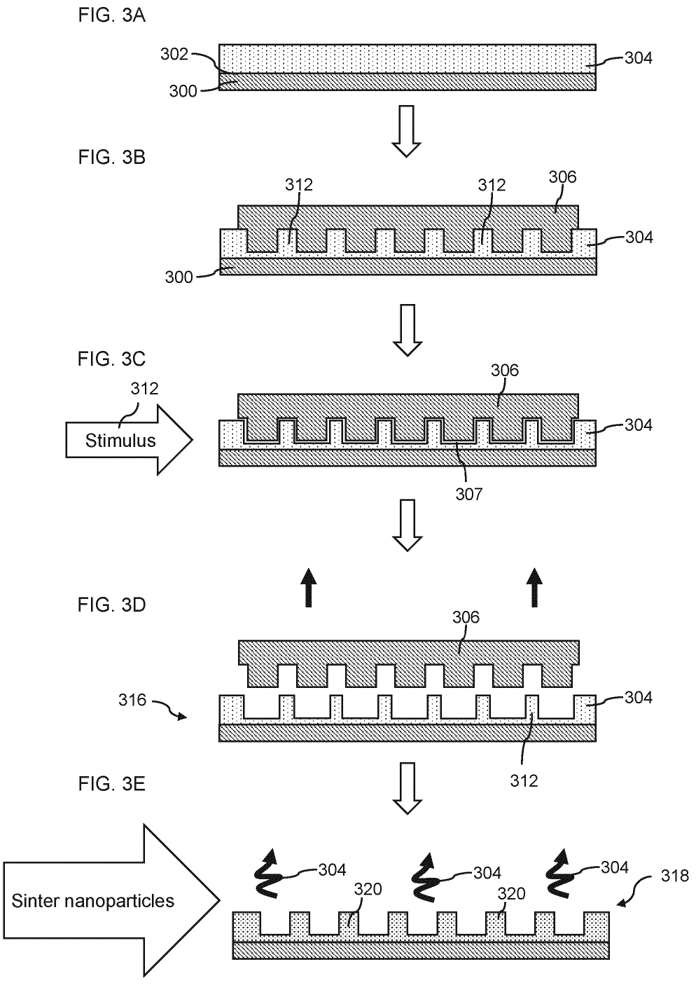

In the example of FIGS. 3A-3E, a replication material 304 is disposed on a surface 302 of a substrate 300, and a stamp 306 is brought into contact with the replication material 304. Except where indicated otherwise, the process, materials, and structures included in the example of FIGS. 3A-3E are the same as, or include a subset of, those described in reference to FIGS. 1A-1D.

In the example of FIGS. 3A-3E, a plurality of nanoparticles (not shown) are embedded in the replication material 304, and at least some of these nanoparticles are NTE nanoparticles, i.e., nanoparticles that include a material having a negative thermal expansion coefficient. In some implementations, each NTE nanoparticle is entirely made from an NTE material. In some implementations, each NTE nanoparticle includes one or more NTE materials and one or more non-NTE materials.

As shown in FIG. 3C, a stimulus 314 is applied to the replication material 304. In this example, the stimulus 314 includes heat, and the stimulus 314 is applied while the stamp 306 is maintained in contact with the replication material 304. As the temperature increases, the NTE nanoparticles in the replication material 304 correspondingly shrink, such that a total volume of the mixture that includes the replication material 304 and the nanoparticles shrinks.

In some implementations, this shrinkage opens up a gap 307 between the replication material 304 and the stamp 306. When the stamp 306 is subsequently removed as shown in FIG. 3D, the presence of the gap 307 means that damage to the replication material 304 (e.g., structures 312 formed in the imprinted replication material), the substrate 300, and/or the stamp 306 itself is reduced, compared to possible damage in the absence of the NTE nanoparticles embedded in the replication material 304. In some implementations, the presence of the NTE nanoparticles may reduce damage by causing compaction and/or densification of the mixture of the nanoparticles and the replication material 304, even when (as is the case in some implementations) a well-defined gap is not formed between the heated replication material 304 and the stamp 306.

The embedded nanoparticles have a high affinity for the replication material 304, such that the nanoparticles remain dispersed in the replication material 304 as imprinting occurs. In some implementations, the replication material 304 has a higher affinity for the nanoparticles than for the stamp 306.

The NTE nanoparticles may include one or more of a variety of materials. In some implementations, the NTE nanoparticles include zirconium tungstate (ZrW₂O₈) or another AM₂O₈ material, where A is Zr or Hf, and M is Mo or W. In some implementations, the NTE nanoparticles include a metal oxide (e.g., CuO). In some implementations, the NTE nanoparticles include an oxide including one or more of Hf, V, Zr, or W.

In some implementations, some or all of the NTE nanoparticles have a high index of refraction, as described elsewhere in this disclosure. At least because NTE nanoparticles may have high refractive indices (e.g., ZrW₂O₈ has a refractive index of 1.9), in some implementations the presence of NTE nanoparticles provides an improvement in optical functionality based on the high refractive index, as described throughout this disclosure.

NTE materials may be characterized by their negative thermal expansion coefficient. In some implementations, the NTE nanoparticles have a thermal expansion coefficient that is less than zero and greater than about −70×10⁻⁶ K⁻¹. In some implementations, the NTE nanoparticles have a thermal expansion coefficient that is less than zero and greater than about −15×10⁻⁶ K⁻¹.

In various implementations, the replication material 304 is heated to temperatures greater than about 100° C., greater than about 150° C., greater than about 200° C., or greater than about 250° C. In some implementations, this temperature is maintained until the stamp 306 is removed from contact with the replication material.

In some implementations, besides heat, the stimulus 314 includes UV illumination. In some implementations, the replication material 304 is UV-curable; in such implementations, heat, while not required to cure the replication material 304, is applied in order to cause contraction of the mixture of the replication material 304 and the NTE nanoparticles. Various profiles and timings of heat and/or UV exposure may be used in order to cure the replication material 304 and also cause the contraction while maintaining intact the structures 312 formed in the imprinting process.

As shown in FIG. 3D, the stamp 306 is removed to leave a resulting optical device 316, as described in reference to optical device 116. In some implementations, because of the NTE nanoparticles included during the imprinting process, the optical device 316 (e.g., structures 312 of the replication material 304, which are, in some implementations, one or more optical metastructures) is more structurally intact than if there were no NTE nanoparticles embedded in the replication material 304. In some implementations, this may lead to improved optical characteristics.

In some implementations, the multimodal nanoparticle distribution described in reference to FIGS. 1A-1D is combined with an NTE nanoparticle implementation as described in reference to FIGS. 3A-3E. That is, in some implementations, nanoparticles are embedded in a replication material, at least a portion of the nanoparticles are NTE nanoparticles, and the nanoparticles have sizes (e.g., diameters) that have a multimodal distribution.

For example, in some implementations, a first subset of the nanoparticles are NTE nanoparticles and have diameters distributed about a first local maximum d₁, and a second subset of the nanoparticles are NTE nanoparticles and have diameters distributed about a second local maximum d₂, wherein d₂ differs from d₁, and the overall diameter distribution is multimodal. In some implementations, one or more subsets of nanoparticles are NTE nanoparticles having diameters distributed about respective local maxima, and one or more other subsets of nanoparticles are non-NTE nanoparticles having diameters distributed about other respective local maxima, at least some of the non-NTE nanoparticles having (in some implementations) a higher refractive index than at least some of the NTE nanoparticles, and the overall diameter distribution being multimodal.

For example, in some implementations, a first subset of nanoparticles is ZrW₂O₈ NTE nanoparticles having diameters distributed about a first local maximum, and a second subset of nanoparticles is TiO₂ non-NTE nanoparticles having diameters distributed about a second, different local maximum. The ZrW₂O₈ nanoparticles provide enhanced structural stability during the fabrication process and also, by their relatively high refractive index, may contribute to improved optical performance. The TiO₂ nanoparticles have an even higher refractive index than do the ZrW₂O₈ nanoparticles and, at least because of the refractive index of the TiO₂ nanoparticles, also can contribute to improved optical performance. The bimodal diameter distribution improves nanoparticle packing density within the replication material, causing a more uniformly high refractive index for the mixture of the replication material and the nanoparticles.

Different types of nanoparticles may be used in different ratios in order to optimize structural stability and/or device optical performance. For example, in some implementations TiO₂ nanoparticles represent about 80% of the nanoparticles and ZrW₂O₈ nanoparticles represent about 20% of the nanoparticles. In some implementations, the non-NTE nanoparticles have a higher refractive index than do the NTE nanoparticles, and the selection of a ratio of non-NTE nanoparticles to NTE nanoparticles involves a balance between improved optical performance (by a higher proportion of non-NTE nanoparticles) and improved thermal expansion properties (by a higher proportion of NTE nanoparticles). However, in some implementations, a higher proportion of NTE nanoparticles does not necessarily lead to improved thermal expansion properties.

FIG. 3E shows an example of a sintering process that, in some implementations, is performed on an imprinted replication material having embedded nanoparticles. In some implementations, the nanoparticles subjected to the sintering process include NTE nanoparticles and/or have sizes distributed according to a multimodal distribution; however, in some implementations the embedded nanoparticles in a sintering process are neither NTE nanoparticles nor have sizes distributed according to a multimodal distribution.

As shown in FIG. 3E, the replication material 304 is removed, and the nanoparticles embedded in the replication material 304 are sintered (densified) to form imprinted sintered structures 320 composed of the nanoparticles, now fused to one another. An optical device 318 includes these sintered structures 320 disposed on the substrate 300. The replication material 304 may be removed by, for example, being burned off and/or being vaporized.

The sintered structures 320 do not include the replication material 304, or include less replication material 304 than was present before removal of the replication material. In some implementations, the sintered structures 320 have dimensions and shapes matching dimensions and shapes of the structures 312 formed before sintering. Because of the removal of the replication material 304 and the sintering of the embedded nanoparticles, the sintered structures 320 are densified compared to the structures 312.

In some implementations, the sintered structures 320 have an optical functionality as described throughout this disclosure, e.g., in some implementations the sintered structures 320 form one or more optical metastructures that perform one or more optical functions (e.g., lensing). The sintered structures 320 may exhibit improved optical characteristics (e.g., a higher and/or more uniform refractive index) because of the removal of the replication material 304 and the sintering of the nanoparticles.

In some implementations the replication material 304 is burned off by a first heat treatment, and the nanoparticles are sintered by either the first heat treatment (e.g., simultaneously to removing the replication material) or by a second, distinct heat treatment. For example, in some implementations, the replication material 304 is configured to be removed by a heat treatment at temperature T₁, and T₁ is sufficient to also sinter the embedded nanoparticles. In some implementations, the nanoparticles are sintered at a second temperature T₂>T₁. In some implementations, the replication material is removed and/or the nanoparticles are sintered by a process besides heat treatment, e.g., a chemical treatment or a laser treatment. In some implementations, one sintering process (e.g., one heat treatment or one laser treatment) both causes the removal of at least some of the replication material and also causes the nanoparticles to sinter.

In some implementations, when at least a portion of the embedded nanoparticles are NTE nanoparticles, the structures 312 and 320 may exhibit reduced dimensional changes compared to if none of the embedded nanoparticles were NTE nanoparticles. In some implementations, this causes a closer match between the initially-imprinted structures 312 and the sintered structures 320. In some implementations, this reduces mechanical damage that may otherwise be caused to the substrate 300 and/or the sintered structures 320, e.g., by the replication material removal process or by the sintering process. In addition, subsequent to sintering, sintered nanoparticles having a multimodal size distribution may exhibit improved mechanical properties (e.g., fracture resistance) compared to sintered nanoparticles having a monomodal size distribution.

In some implementations, when the embedded nanoparticles have sizes distributed according to a multimodal distribution, the sintered structures 320 may have an improved density (e.g., a more uniform and/or higher refractive index) compared to if the embedded nanoparticles did not have sizes distributed according to a multimodal distribution. This may be caused by the improved packing density of the nanoparticles having the multimodal size distribution.

Although the optical devices described in this disclosure (e.g., optical device 318) are sometimes described as resulting from particular fabrication processes (e.g., the imprinting fabrication process of FIGS. 3A-3E), in some implementations an optical device formed from sintered nanoparticles (e.g., NTE nanoparticles and/or nanoparticles having a multimodal size distribution), or an optical device including nanoparticles embedded in a replication material, is fabricated using another method. In such implementations, the nanoparticles may provide the advantages described throughout this disclosure (e.g., improved packing density) regardless of a fabrication method of the optical device.

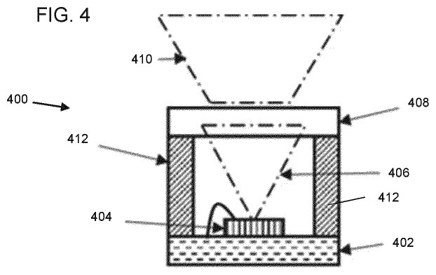

In some implementations, devices as described throughout this disclosure (e.g., devices including NTE nanoparticles and/or nanoparticles having a multimodal size distribution, in some implementations embedded in a replication material), may be integrated, for example, into optical or optoelectronic systems. As shown in FIG. 4, a module 400 includes a substrate 402 and a light-emitting component 404 coupled to or integrated into the substrate 402. The light-emitting component 404 may include, for example, a laser (for example, a vertical-cavity surface-emitting laser) or a light-emitting diode.

Light 406 generated by the light-emitting component 404 is transmitted through a housing and then to an optical device 408, e.g., optical devices 116, 316, or 318. The optical device 408 is operable to interact with the light 406, such that modified light 410 is transmitted out of the module 400. For example, the module 400, using the optical device 408, may produce one or more of structured light, diffused light, or patterned light. The housing may include, for example, spacers 412 separating the light-emitting component 404 and/or the substrate 402 from the optical device 408.

In some implementations, the module 400 of FIG. 4 is a light-sensing module (for example, an ambient light sensor), the component 404 is a light-sensing component (for example, a photodiode, a pixel, or an image sensor), the light 406 is incident on the module 400, and the light 410 is modified by the optical device 408. For example, the optical device 408 may focus patterned light onto the light-sensing component 404.

In some implementations, the module 400 may including both light-emitting and light-sensing components. For example, the module 400 may emit light that interacts with an environment of the module 400 and is then received back by the module 400, allowing the module 400 to act, for example, as a proximity sensor or as a three-dimensional mapping device.

The modules described above may be part of, for example, time-of-flight cameras or active-stereo cameras. The modules may be integrated into systems, for example, mobile phones, laptops, television, wearable devices, or automotive vehicles.

The optical device 408 may provide advantages to the module 400 compared to modules that do not include an optical device 408 as described in this disclosure. For example, because of the inclusion of NTE nanoparticles in the optical device 408, mechanical damage in the module 400 may be reduced (e.g., a yield of fabricating the module 400 may be increased). In some implementations, because the optical device 408 includes nanoparticles having a multimodal size distribution, optical characteristics of the optical device 408 and the module 400 are improved. In some implementations, because sintered nanoparticles in the optical device 408 have a multimodal size distribution, mechanical robustness of the optical device 408 and the module 400 is improved.

In this disclosure, references to refractive indices and thermal expansion coefficients refer to values of these properties at room temperature (e.g., 25 C).

Therefore, in accordance with the implementations of this disclosure, optical devices including nanoparticles and methods of fabricating these optical devices, are described.

Although this disclosure sometimes refers to optical devices, the methods, devices, and modules described are not limited to, nor required to include, optical functionality. For example, in some implementations, nanoparticles are embedded in a replication material and provide a non-optical improvement or functionality.

It should be noted that any of the above-noted embodiments may be provided in combination or individually. Elements of different embodiments described herein may be combined to form other embodiments not specifically set forth above.

Accordingly, other implementations are also within the scope of the claims.

1. A method comprising:
pressing a face of a stamp into a replication material disposed on a substrate, to cause the replication material to have a predetermined characteristic,
wherein a plurality of nanoparticles are embedded in the replication material, the plurality of nanoparticles having a size distribution with a first local maximum at a first diameter and a second local maximum at a second, different diameter, and
wherein the plurality of nanoparticles includes a first subset of nanoparticles having diameters closer to the first diameter than to the second diameter and a second subset of nanoparticles having diameters closer to the second diameter than to the first diameter;
curing the replication material; and
removing the face of the stamp from contact with the replication material.

2. The method of claim 1, wherein nanoparticles in the first subset have a first refractive index, and wherein nanoparticles in the second subset have a second refractive index different from the first refractive index.

3. The method of claim 1, wherein at least some of the plurality of nanoparticles have a negative thermal expansion coefficient.

4. The method of claim 3, wherein the nanoparticles having the negative thermal expansion coefficient are exclusively in the first subset or the second subset of the plurality of nanoparticles.

5. The method of claim 1, wherein the first diameter and the second diameter are different by at least about 20 nm.

6. The method of claim 1, comprising, subsequent to removing the face of the stamp, sintering the nanoparticles to one another, wherein the sintered nanoparticles form one or more optical metastructures.

7. The method of claim 6, wherein sintering the nanoparticles comprises removing at least a portion of the replication material.

8. The method of claim 1, wherein the predetermined characteristic comprises a surface structure of the replication material.

9. The method of claim 8, wherein the surface structure provides an optical functionality.

10. The method of claim 1, wherein the predetermined characteristic comprises an optical metastructure functionality.

11. (canceled)

12. The method of claim 3, wherein at least some of the plurality of nanoparticles having a negative thermal expansion coefficient comprise an AM₂O₈ material.

13.-19. (canceled)

20. A method comprising:
pressing a face of a stamp into a replication material disposed on a substrate, to cause the replication material to have a predetermined characteristic,
wherein a plurality of nanoparticles are embedded in the replication material;
curing the replication material; and
sintering the plurality of nanoparticles to form an optical metastructure formed by the plurality of nanoparticles.

21. The method of claim 20, wherein sintering the plurality of nanoparticles causes the removal of at least some of the replication material.

22. The method of claim 20, comprising burning off at least some of the replication material.

23. (canceled)

24. The method of claim 20, wherein the plurality of nanoparticles has a size distribution with a first local maximum at a first diameter and a second local maximum at a second, different diameter.

25. An apparatus comprising an optical device comprising:
a substrate; and
an optical metastructure on a surface of the substrate, the optical metastructure comprising:
a plurality of nanoparticles embedded in a replication material or fused to one another, the plurality of nanoparticles having a size distribution with a first local maximum at a first diameter and a second local maximum at a second, different diameter.

26. The apparatus of claim 25, wherein the plurality of nanoparticles includes a first subset of nanoparticles having diameters closer to the first diameter than to the second diameter and a second subset of nanoparticles having diameters closer to the second diameter than to the first diameter, and
wherein the nanoparticles of the first subset are composed of a different material from the nanoparticles of the second subset.

27. The apparatus of claim 25, wherein at least some of the plurality of nanoparticles have a negative thermal expansion coefficient.

28. (canceled)

29. The apparatus of claim 27, wherein at least some of the plurality of nanoparticles having a negative thermal expansion coefficient comprise an AM₂O₈ material.

30.-36. (canceled)

37. The apparatus of claim 25 further comprising:
at least one of a light-emitting device or a light-sensitive device,
wherein the optical device is configured (i) to interact with light generated by the light emitting device or (ii) to interact with incident such that light passing through the optical device is received by the light-sensitive device.
